(19) United States
(12) Patent Application Publication
(10) Pub. No.: US 2008/0308308 A1
(43) Pub. Date: Dec. 18, 2008

(54) METHOD OF MANUFACTURING WIRING BOARD, METHOD OF MANUFACTURING SEMICONDUCTOR DEVICE AND WIRING BOARD

(75) Inventor: Kazuhiro Kobayashi, Nagano-shi (JP)

Correspondence Address: RANKIN, HILL & CLARK LLP, 38210 Glenn Avenue, WILLOUGHBY, OH, 44094-7808, US

(73) Assignee: SHINKO ELECTRIC INDUSTRIES CO., LTD., Nagano-shi (JP)

(21) Appl. No.: 12/056,514

(22) Filed: Mar. 27, 2008

(30) Foreign Application Priority Data
Mar. 29, 2007 (JP) 2007-089019

(51) Int. Cl. H05K 1/09; H05K 3/40; H01L 21/60

(52) U.S. Cl. 174/257; 29/846; 438/106

(57) ABSTRACT

A semiconductor device 100 has such a structure that a semiconductor chip 110 is flip chip mounted on a wiring board 120. The wiring board 120 has a multilayer structure in which a plurality of wiring layers and a plurality of insulating layers are laminated and insulating layers are laminated as a first layer 122, a second layer 124, a third layer 126 and a fourth layer 128. A second electrode pad 132 is formed to be wider in a radial direction (a planar direction) than an outside diameter of a first electrode pad 130 on a boundary surface between a first insulating layer 121 and a second insulating layer 123. The second electrode pad 132 formed to be wider than the first electrode pad 130 is provided between the first electrode pad 130 and a via 134.

### BACKGROUND OF THE INVENTION

The present invention relates to a method of manufacturing a wiring board, a method of manufacturing a semiconductor device, and the wiring board, and more particularly to a method of manufacturing a wiring board which is constituted to enhance a reliability in an electrode pad forming portion of a multilayer substrate, a method of manufacturing a semiconductor device, and the wiring board.

For example, as a method of forming a ball of a BGA (Ball Grid Array) to be used in a connection of a bare chip and a substrate or a connection of a package substrate and a mother board, there has been known a manufacturing method of forming a plurality of electrodes on a substrate and then forming a solder resist having a hole communicating with the electrode, and fusing a solder ball through a heat treatment (reflow) to bond the fused solder ball to the electrode in the hole in a state in which the solder ball is loaded onto an opening of the hole, and forming a solder bump as a protrusion on a surface of the solder resist.

On the other hand, there has also been advanced a development of a package for mounting a bare chip on a multilayer substrate with a reduction in a size and an increase in an integration in the bare chip (for example, see Patent Document 1).

FIG. 1 shows an example of a structure of a conventional wiring board. With the structure of the substrate shown in FIG. 1, layers are laminated in such a manner that an outer periphery of an electrode pad 10 is covered with a first insulating layer 12 and an upper surface of the electrode pad 10 is covered with a second insulating layer 13, and a via 14 extended upward from a center of an upper surface of the electrode pad 10 penetrates through the second insulating layer 13 and is connected to a wiring portion 16 in an upper part. The electrode pad 10 has such a structure that an Au layer 17 and an Ni layer 18 are laminated, and is provided in such a manner that a surface of the Au layer 17 is exposed from the first insulating layer 12 and the via 14 is connected to the Ni layer 18.

Furthermore, a semiconductor chip is mounted on the electrode pad 10 through a solder bump in some cases and a solder ball or a pin is bonded in the other cases. In a wiring board having a multilayer structure, thus, the electrode pad 10 is used as a bare chip loading pad or an external connecting pad.

### Patent Document 1

Japanese Patent No. 3635219 (JP-A-2000-323613 Publication)

In the wiring board shown in FIG. 1, however, the outer periphery of the electrode pad 10 is comparatively smooth. Therefore, an adhesion to the first insulating layer 12 is poor. When heating is carried out through a reflow treatment, a delamination is generated in a boundary portion provided in contact with the outer periphery of the electrode pad 10 by an application of a thermal stress due to a difference in a thermal expansion between the first insulating layer 12 and the electrode pad 10 so that a part of the first insulating layer 12 might be broken off.

In the case in which a part of the first insulating layer 12 provided in contact with the outer periphery of a corner portion (B portion) of the electrode pad 10 is broken off due to the heating carried out by the reflow treatment, furthermore, there is a problem in that a crack 20 is generated from a corner portion (A portion) of the electrode pad 10 toward the second insulating layer 13.

In the case in which the crack 20 is enlarged, moreover, there is a possibility that the wiring portion 16 provided on the second insulating layer 13 might be cut.

### SUMMARY OF THE INVENTION

In consideration of the circumstances, therefore, it is an object of the invention to provide a method of manufacturing a wiring board, a method of manufacturing a semiconductor device, and the wiring board which solve the problems.

In order to solve the problems, the invention has the following means.

According to a first aspect of the invention, there is provide with a method of manufacturing a wiring board, including:

a first step of forming a first electrode pad on a support substrate;

a second step of laminating, on a surface of the support substrate, a first insulating layer surrounding an outer periphery of the first electrode pad;

a third step of forming a second electrode pad which is wider in a planar direction than the outer periphery of the first electrode pad from a surface of the first electrode pad to that of the first insulating layer;

a fourth step of laminating a second insulating layer on surfaces of the second electrode pad and the first insulating layer;

a fifth step of forming, on a surface of the second insulating layer, a wiring layer to be electrically connected to the second electrode pad; and

a sixth step of removing the support substrate to expose the first electrode pad. Thus, the problems can be solved.

According to a second aspect of the invention, there is provide with the method according to the first aspect, wherein

the second step includes a step of roughening the surface of the first electrode pad before laminating the first insulating layer. Thus, the problems can be solved.

According to a third aspect of the invention, there is provide with the method according to the first or second aspect, wherein

the support substrate is formed of a metal,

the first step includes a step of forming a metal layer of the same type as the support substrate between the support substrate and the first electrode pad, and

the sixth step includes a step of removing the support substrate, removing the metal layer and forming a concave portion by an end face of the first electrode pad. Thus, the problems can be solved.

According to a fourth aspect of the invention, there is provide with a method of manufacturing a semiconductor device using the method of manufacturing a wiring board according to any one of the first to third aspects of the invention, including the step of:

mounting a semiconductor chip on the first electrode pad through a solder bump. Thus, the problems can be solved.

According to a fifth aspect of the invention, there is provide with a wiring board including:

a first electrode pad;

a first insulating layer surrounding an outer periphery of the first electrode pad; and

a second insulating layer laminated on a surface of the first electrode pad and that of the first insulating layer, wherein

a second electrode pad which is wider in a planar direction than an outer periphery of the first electrode pad is provided between the first electrode pad and the second insulating layer. Thus, the problems can be solved.

According to the invention, the second electrode pad which is wider in a planar direction than the outer periphery of the first electrode pad is formed from the surface of the first electrode pad to that of the first insulating layer. Therefore, the second electrode pad which is wider than the first electrode pad can be prevented from generating a crack from the corner portion of the outer periphery of the first electrode pad to the second insulating layer.

### BRIEF DESCRIPTION OF THE DRAWINGS

FIG. 1 is a view showing an example of a structure of a conventional wiring board,

FIG. 2 is a longitudinal sectional view showing a semiconductor device to which a first embodiment of a wiring board according to the invention is applied,

FIG. 3A is a view for explaining a method (No. 1) of manufacturing a wiring board according to the first embodiment,

FIG. 3B is a view for explaining the method (No. 2) of manufacturing a wiring board according to the first embodiment,

FIG. 3C is a view for explaining the method (No. 3) of manufacturing a wiring board according to the first embodiment,

FIG. 3D is a view for explaining the method (No. 4) of manufacturing a wiring board according to the first embodiment,

FIG. 3E is a view for explaining the method (No. 5) of manufacturing a wiring board according to the first embodiment,

FIG. 3F is a view for explaining the method (No. 6) of manufacturing a wiring board according to the first embodiment,

FIG. 3G is a view for explaining the method (No. 7) of manufacturing a wiring board according to the first embodiment,

FIG. 3H is a view for explaining the method (No. 8) of manufacturing a wiring board according to the first embodiment,

FIG. 3I is a view for explaining the method (No. 9) of manufacturing a wiring board according to the first embodiment,

FIG. 3J is a view for explaining the method (No. 10) of manufacturing a wiring board according to the first embodiment,

FIG. 3K is a view for explaining the method (No. 11) of manufacturing a wiring board according to the first embodiment,

FIG. 3L is a view for explaining the method (No. 12) of manufacturing a wiring board according to the first embodiment,

FIG. 3M is a view for explaining the method (No. 13) of manufacturing a wiring board according to the first embodiment,

FIG. 3N is a view for explaining the method (No. 14) of manufacturing a wiring board according to the first embodiment,

FIG. 3O is a view for explaining the method (No. 15) of manufacturing a wiring board according to the first embodiment,

FIG. 3P is a view for explaining the method (No. 16) of manufacturing a wiring board according to the first embodiment,

FIG. 3Q is a view for explaining the method (No. 17) of manufacturing a wiring board according to the first embodiment,

FIG. 3R is a view for explaining the method (No. 18) of manufacturing a wiring board according to the first embodiment,

FIG. 3S is a view for explaining the method (No. 19) of manufacturing a wiring board according to the first embodiment,

FIG. 3T is a view for explaining the method (No. 20) of manufacturing a wiring board according to the first embodiment,

FIG. 4 is a view showing a variant of the first embodiment,

FIG. 5 is a longitudinal sectional view showing a semiconductor device to which a second embodiment of the wiring board is applied,

FIG. 6A is a view for explaining a method (No. 1) of manufacturing a wiring board according to the second embodiment,

FIG. 6B is a view for explaining the method (No. 2) of manufacturing a wiring board according to the second embodiment,

FIG. 6C is a view for explaining the method (No. 3) of manufacturing a wiring board according to the second embodiment,

FIG. 6D is a view for explaining the method (No. 4) of manufacturing a wiring board according to the second embodiment,

FIG. 6E is a view for explaining the method (No. 5) of manufacturing a wiring board according to the second embodiment,

FIG. 6F is a view for explaining the method (No. 6) of manufacturing a wiring board according to the second embodiment,

FIG. 6G is a view for explaining the method (No. 7) of manufacturing a wiring board according to the second embodiment,

FIG. 6H is a view for explaining the method (No. 8) of manufacturing a wiring board according to the second embodiment,

FIG. 6I is a view for explaining the method (No. 9) of manufacturing a wiring board according to the second embodiment,

FIG. 6J is a view for explaining the method (No. 10) of manufacturing a wiring board according to the second embodiment,

FIG. 6K is a view for explaining the method (No. 11) of manufacturing a wiring board according to the second embodiment,

FIG. 6L is a view for explaining the method (No. 12) of manufacturing a wiring board according to the second embodiment,

FIG. 6M is a view for explaining the method (No. 13) of manufacturing a wiring board according to the second embodiment,

FIG. 6N is a view for explaining the method (No. 14) of manufacturing a wiring board according to the second embodiment,

FIG. 6O is a view for explaining the method (No. 15) of manufacturing a wiring board according to the second embodiment,

FIG. 6P is a view for explaining the method (No. 16) of manufacturing a wiring board according to the second embodiment,

FIG. 6Q is a view for explaining the method (No. 17) of manufacturing a wiring board according to the second embodiment,

FIG. 6R is a view for explaining the method (No. 18) of manufacturing a wiring board according to the second embodiment,

FIG. 6S is a view for explaining the method (No. 19) of manufacturing a wiring board according to the second embodiment,

FIG. 6T is a view for explaining the method (No. 20) of manufacturing a wiring board according to the second embodiment, and

FIG. 7 is a view showing a variant of the second embodiment.

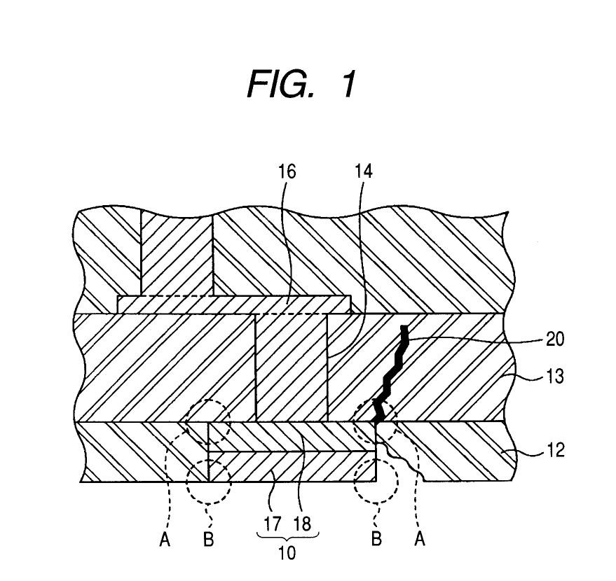

### DETAILED DESCRIPTION OF THE PREFERRED EMBODIMENTS

The best mode for carrying out the invention will be described below with reference to the drawings.

### First Embodiment

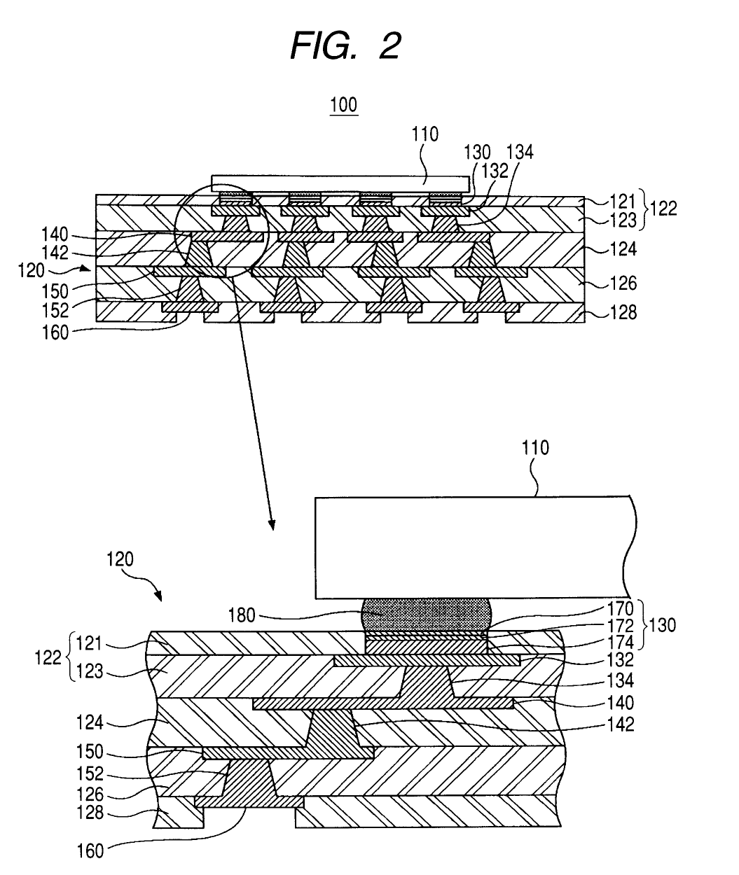

FIG. 2 is a longitudinal sectional view showing a semiconductor device to which a first embodiment of a wiring board according to the invention is applied. As shown in FIG. 2, a semiconductor device 100 has a structure in which a semiconductor chip 110 is flip chip mounted on a wiring board 120, for example. The wiring board 120 has a multilayer structure in which a plurality of wiring layers and a plurality of insulating layers are laminated. In the embodiment, insulating layers to be a first layer 122, a second layer 124, a third layer 126 and a fourth layer 128 which have wiring layers are laminated in a vertical direction. Moreover, the first layer 122 has such a structure that a first insulating layer 121 and a second insulating layer 123 are laminated in order to carry out a step of providing a second wide electrode pad 132 on a first electrode pad 130. Each of the insulating layers is formed by an insulating resin such as an epoxy resin or a polyimide resin.

The first insulating layer 121 and the fourth layer 128 which are subjected to a solder connection may be formed by an insulating resin to be a solder resist (formed by an acrylic resin or an epoxy resin). In the semiconductor device 100, moreover, an underfill resin having an insulating property may be filled between the semiconductor chip 110 and the wiring board 120.

The first layer 122 in an uppermost stage is provided with the first electrode pad 130, the second electrode pad 132 and a via 134 to which a terminal of the semiconductor chip 110 is flip chip connected. Moreover, the second layer 124 laminated under the first layer 122 is provided with a wiring layer 140 and a via 142 which are conducted to the via 134. Furthermore, the third layer 126 laminated under the second layer 124 has a wiring layer 150 and a via 152 which are conducted to the via 142. In addition, the fourth layer 128 provided under the third layer 126 has a third electrode pad 160 conducted to the via 152.

In the first layer 122, moreover, the first insulating layer 121 is formed to surround the outer periphery of the first electrode pad 130 and the second electrode pad 132 is formed between the first insulating layer 121 and the second insulating layer 123.

The first electrode pad 130 has a three-layer structure in which an Au layer 170, an Ni layer 172 and a Cu layer 174 that have an excellent bonding property to a solder are provided. The Au layer 170 is exposed to an upper surface side of the wiring board 120 (a semiconductor chip mounting side) and a solder bump 180 of the semiconductor chip 110 is connected to the Au layer 170.

A terminal of the semiconductor chip 110 is soldered to the Au layer 170 through the solder bump 180 and is thus conducted to the first electrode pad 130. The solder bump 180 is formed by loading a solder ball onto the first electrode pad 130 and carrying out a reflow (a heat treatment).

The second electrode pad 132 which is wider than the first electrode pad 130 is formed on a boundary surface between the first insulating layer 121 and the second insulating layer 123. The second electrode pad 132 is formed widely to be protruded from an outside diameter of the first electrode pad 130 in a radial direction (a planar direction). In the embodiment, if the first electrode pad 130 has a diameter of approximately 70 to 100 μm and a thickness of approximately 15 μm (±10 μm), the second electrode pad 132 has a diameter which is greater than that of the first electrode pad 130 by approximately 20 to 90% (suitably 50 to 80%) and has a thickness of approximately 2 to 15 μm (suitably 5 μm), for instance.

The second electrode pad 132 which is wider than the first electrode pad 130 is provided between the first electrode pad 130 and the via 134. Consequently, a direction of advance of a thermal stress through the reflow treatment is blocked by the second electrode pad 132 and is absorbed in a direction along the boundary surface between the first insulating layer 121 and the second insulating layer 123, for example. Even if a delamination is caused in a part of the first insulating layer 121 covering the outer periphery of the first electrode pad 130 so that the first insulating layer 121 is broken off, therefore, a crack can be prevented from being generated on the second insulating layer 123.

As the first electrode pad 130, it is also possible to employ a structure in which only the Au layer 170 and the Ni layer 172 are laminated in such a manner that the Au layer 170 is exposed to a surface of the wiring board 120. Moreover, the first electrode pad 130 may have another plating structure, for example, a structure in which a lamination is carried out in order of the Au layer, the Pd layer, the Ni layer and the Cu layer or order of the Au layer, the Pd layer and the Ni layer in such a manner that the Au layer 170 is exposed to the surface of the wiring board 120.

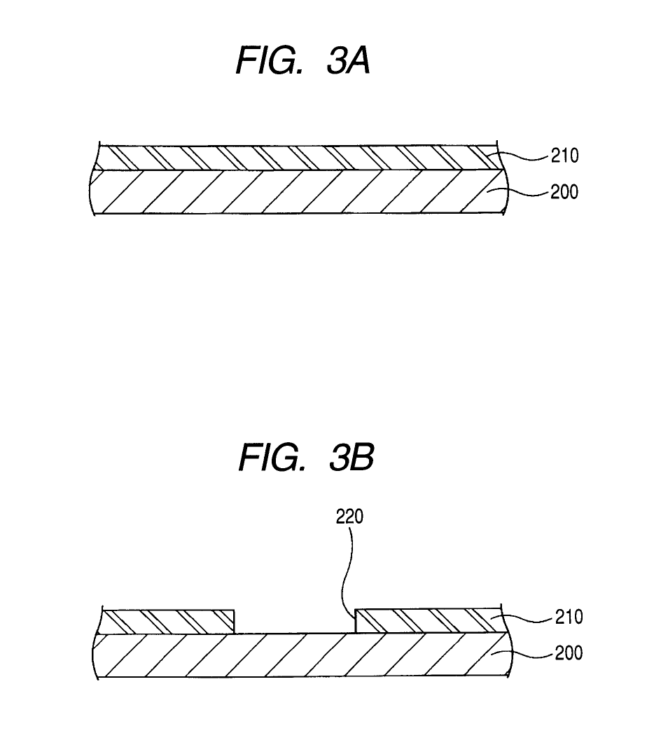

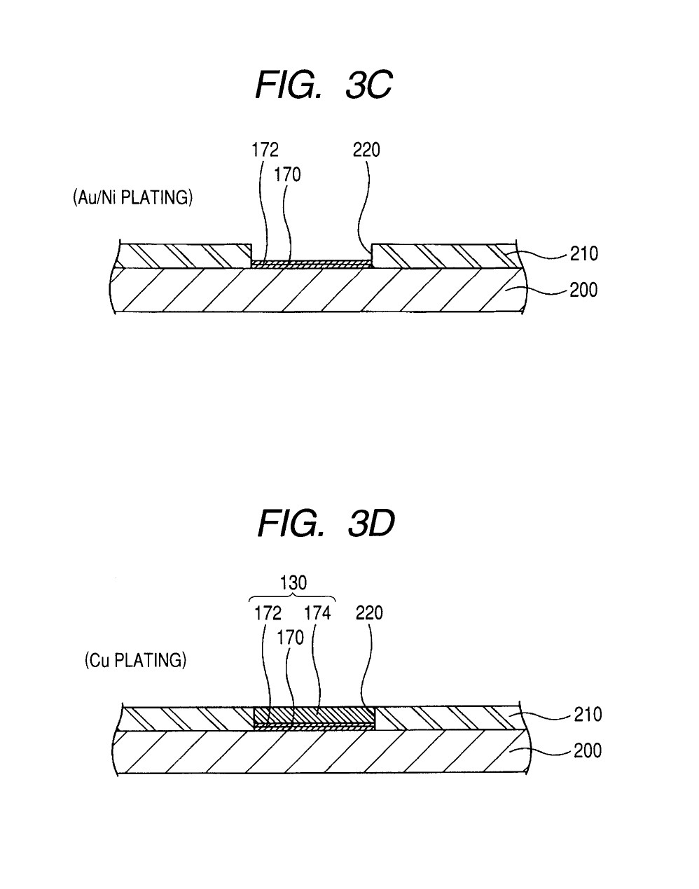

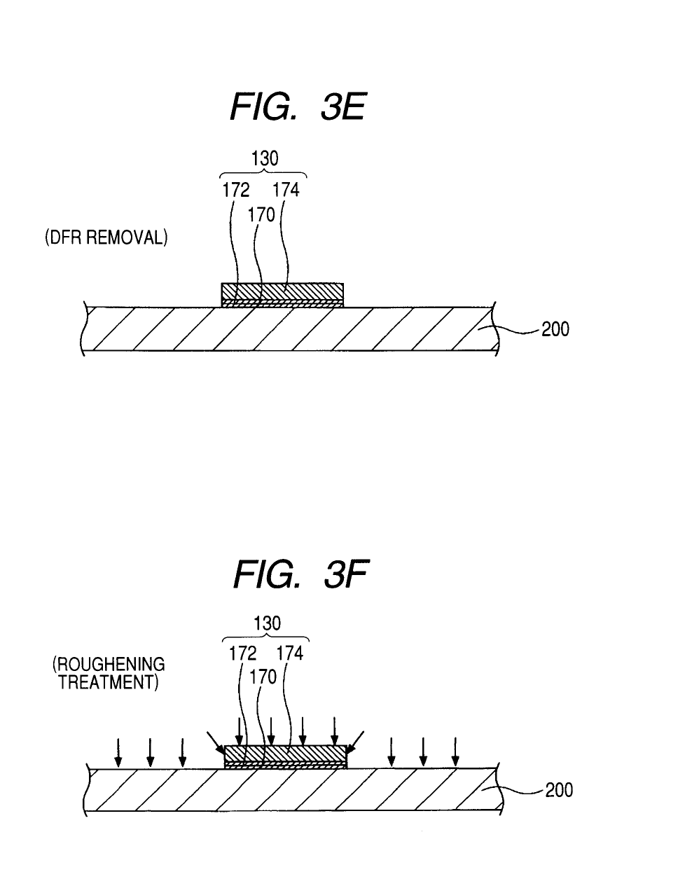

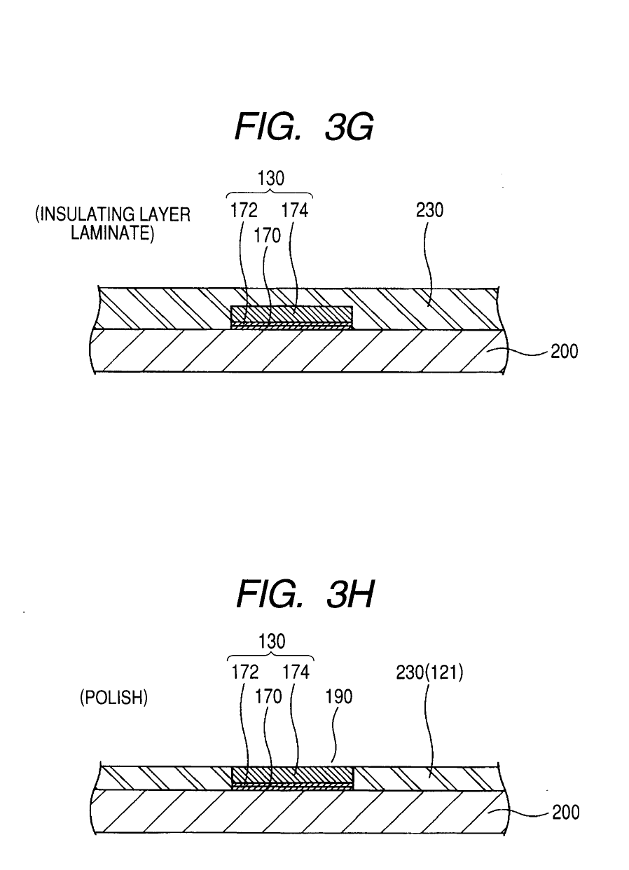

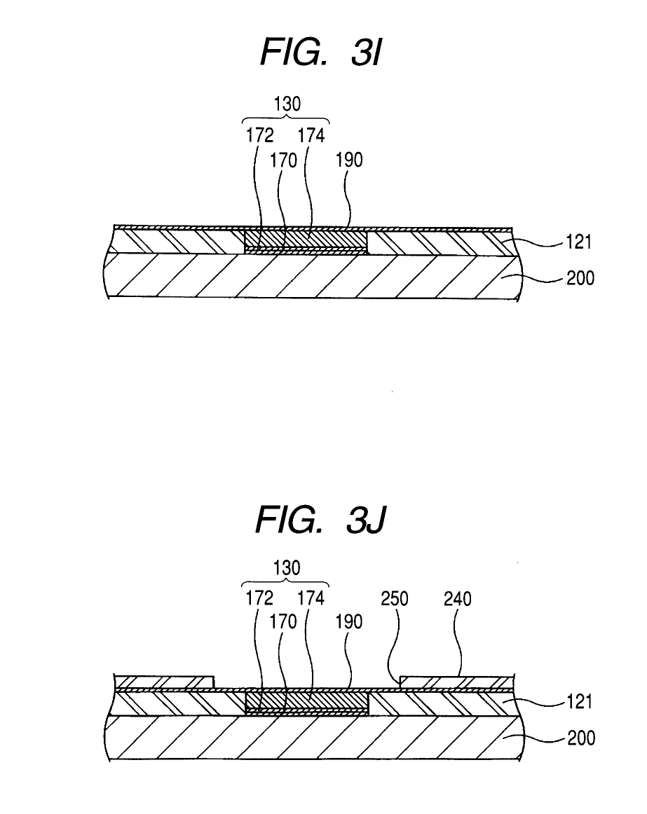

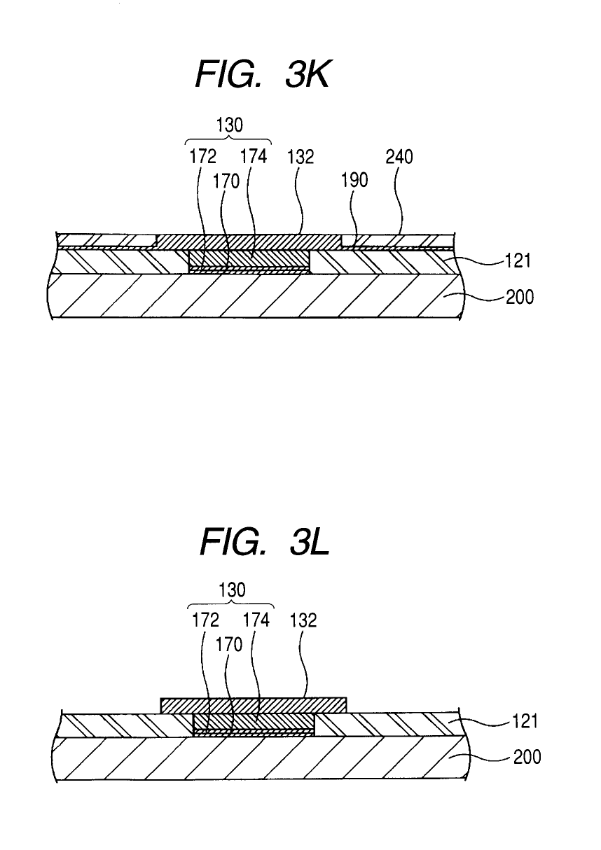

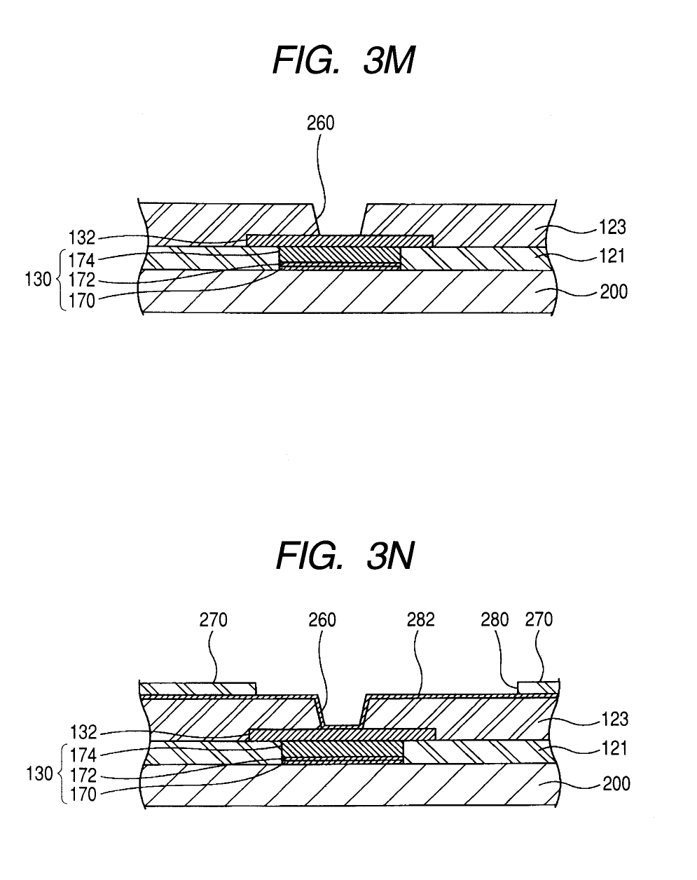

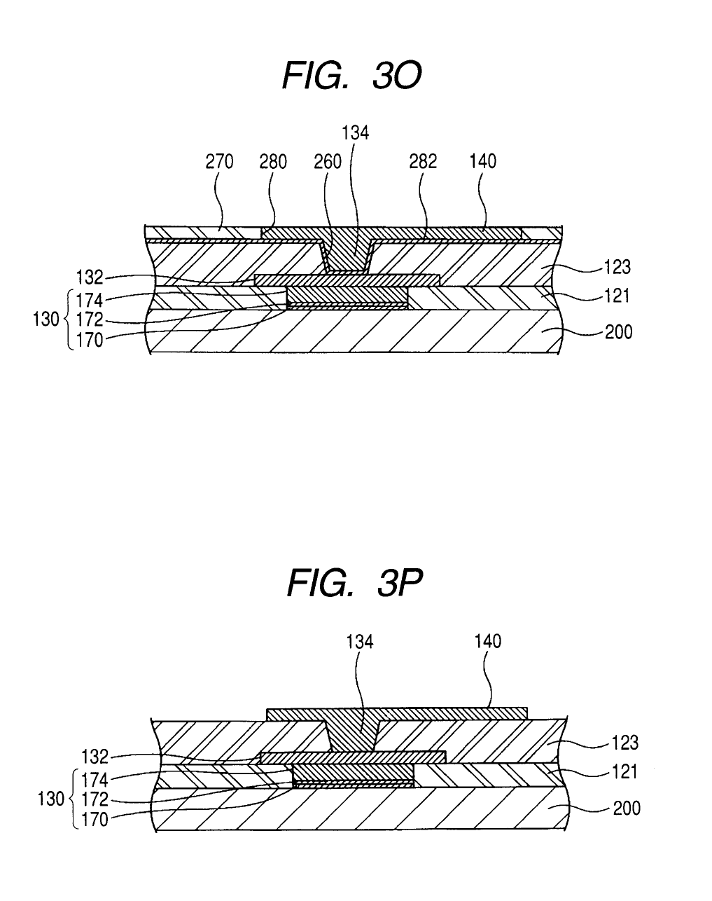

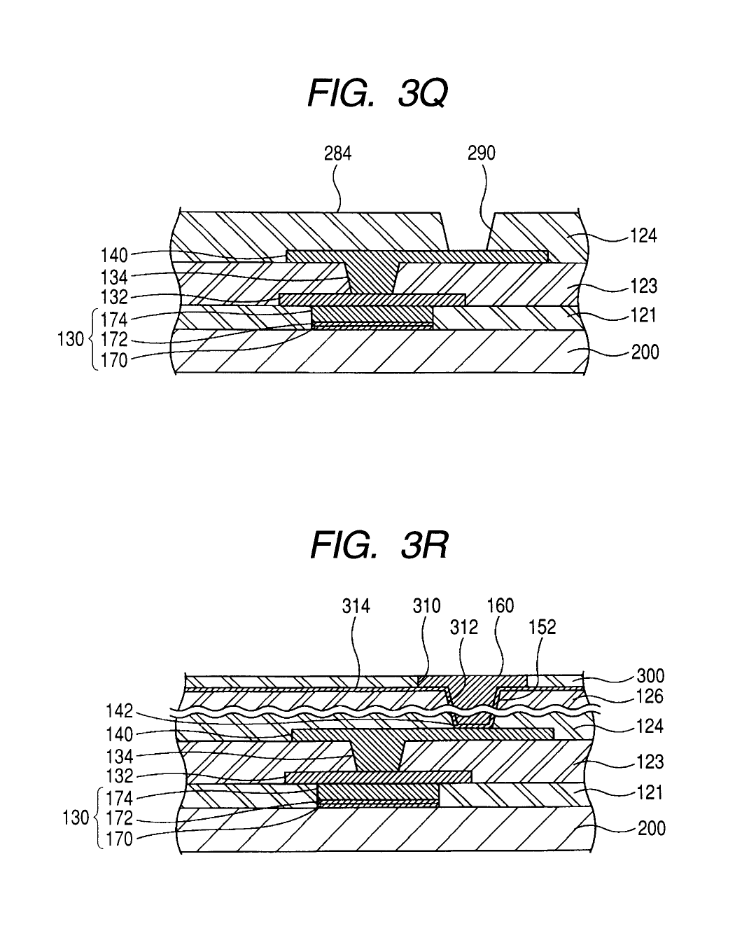

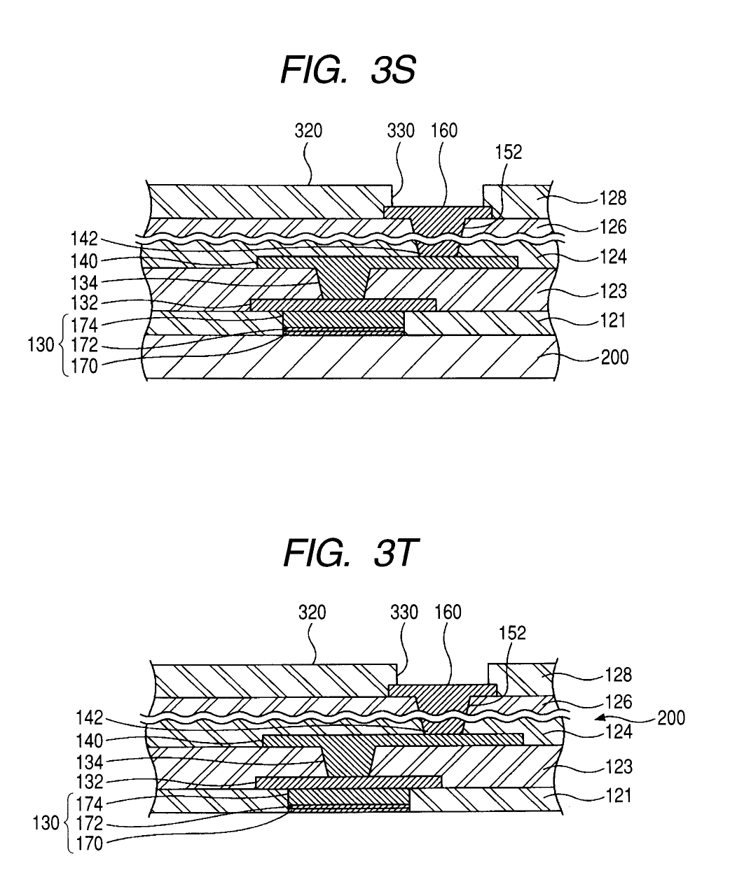

A method of manufacturing the wiring board 120 to be used in the semiconductor device 100 will be described with reference to FIGS. 3A to 3T. FIGS. 3A to 3T are views for explaining the methods (No. 1 to No. 20) of manufacturing the wiring board 120 according to the first embodiment. In FIGS. 3A to 3T, the respective layers are provided facedown (a vertically reverse direction to the lamination structure shown in FIG. 2) with the first electrode pad 130 provided on a lower surface side of the wiring board 120.

In FIG. 3A, first of all, a support substrate 200 formed by a flat Cu plate or a Cu foil having a predetermined thickness is prepared. Then, a dry film resist 210 is laminated as a plating resist on an upper surface of the support substrate 200.

In FIG. 3B, a first electrode pad forming opening 220 for exposing a part of the support substrate 200 is formed on the dry film resist 210 through an exposure. An inside diameter of the first electrode pad forming opening 220 is equivalent to an outside diameter of the first electrode pad 130.

In FIG. 3C, electrolytic plating is carried out by setting the support substrate 200 as a feeding layer to deposit Au on the support substrate 200 in the first electrode pad forming opening 220, thereby forming the Au layer 170, and furthermore, to deposit Ni on the surface of the Au layer 170, thereby laminating the Ni layer 172.

In FIG. 3D, furthermore, the electrolytic plating is carried out by setting the support substrate 200 as a feeding layer to deposit Cu on the Ni layer 172 in the first electrode pad forming opening 220, thereby laminating the Cu layer 174. Thus, the first electrode pad 130 is formed. Consequently, the first electrode pad 130 having a three-layer structure formed by the Au layer 170, the Ni layer 172 and the Cu layer 174 is provided in the first electrode pad forming opening 220.

In FIG. 3E, the dry film resist 210 is peeled from the support substrate 200 so that the first electrode pad 130 is left on the support substrate 200 in a laminating state.

In FIG. 3F, the surfaces of the support substrate 200 and the electrode pad 130 are subjected to a roughening treatment (for example, a half etching treatment) to roughen the surfaces of the support substrate 200 and the first electrode pad 130. It is preferable that a surface roughness obtained by the roughening treatment should have Ra=approximately 0.25 to 0.75 μm, for example.

In FIG. 3G, a resin film such as an epoxy resin or a polyimide resin is laminated on the surfaces of the support substrate 200 and the electrode pad 130 which are subjected to the roughening treatment so that an insulating layer 230 is formed. Since the surfaces of the support substrate 200 and the first electrode pad 130 are roughened, an adhesion of the insulating layer 230 to the electrode pad 130 is enhanced so that a delamination can be prevented from being generated due to a thermal stress.

In FIG. 3H, an upper surface of the insulating layer 230 bonded to the surfaces of the support substrate 200 and the first electrode pad 130 is subjected to buffing. The buffing treatment is carried out until the surface of the first electrode pad 130 is exposed. Consequently, the first insulating layer 121 covering the outer periphery of the first electrode pad 130 is obtained.

In FIG. 3I, a seed layer 190 is formed on the flattened surfaces of the first insulating layer 121 and the first electrode pad 130 by electroless plating of Cu. As a method of forming the seed layer 190, another thin film forming method (a sputtering method or a CVD method) maybe used or a conductive metal other than Cu may be formed. In order to enhance a bonding property, moreover, it is also possible to carry out the roughening treatment over the surfaces of the first insulating layer 121 and the first electrode pad 130, thereby forming the seed layer.

In FIG. 3J, a dry film resist 240 is laminated as a plating resist on the surfaces (upper surfaces) of the first insulating layer 121 and the first electrode pad 130 on which the seed layer 190 is formed. Then, patterning (exposure and development) is carried out over the dry film resist 240 to form a second electrode pad forming opening 250 for exposing a part of the seed layer 190. An inside diameter of the second electrode pad forming opening 250 is equivalent to an outside diameter of the second electrode pad 132, and a depth of the second electrode pad forming opening 250 defines a height (a thickness) of the second electrode pad 132.

In FIG. 3K, electrolytic Cu plating is carried out by feeding from the seed layer 190 to deposit Cu in the second electrode pad forming opening 250, thereby forming the second electrode pad 132 having a larger diameter than the first electrode pad 130. Consequently, the second electrode pad 132 having a large diameter in a radial direction (a planar direction) is laminated on the surface of the first electrode pad 130.

In FIG. 3L, the dry film resist 240 is removed from the seed layer 190, and furthermore, the seed layer 190 in portions other than the portions provided under the second electrode pad 132 is removed from the first insulating layer 121. Consequently, the second electrode pad 132 is left on the first insulating layer 121. At steps shown in and after FIG. 3L, Cu is integrated in the seed layer 190 provided under the second electrode pad 132, and the seed layer 190 is therefore omitted.

In FIG. 3M, a roughening treatment (for example, a half etching treatment) is carried out over the surface of the second electrode pad 132 and a resin film such as an epoxy resin or a polyimide resin is then laminated to form the second insulating layer 123. Consequently, the first layer 122 having the first electrode pad 130 and the second electrode pad 132 is obtained. Then, a laser beam is irradiated on the second insulating layer 123 to form a via hole 260 in such a manner that a center of the surface of the second electrode pad 132 is exposed, for example.

In FIG. 3N, a seed layer 282 is formed on a surface of the second insulating layer 123 and an internal surface of the via hole 260 through nonelectrolytic Cu plating. Subsequently, a dry film resist 270 is laminated as a plating resist on the surface (the upper surface) of the second insulating layer 123. Then, patterning (exposure and development) is carried out over the dry film resist 270 to form a wiring pattern forming opening 280 for exposing a part of the seed layer 282.

In FIG. 3O, the electrolytic Cu plating is carried out by feeding from the seed layer 282 to deposit Cu on the seed layer 282 in the via hole 260 and the wiring pattern forming opening 280 so that the via 134 and the wiring pattern layer 140 are formed.

In FIG. 3P, the dry film resist 270 is removed from the seed layer 282, and furthermore, the seed layer 282 in portions other than the portions provided under the wiring pattern layer 140 is removed from the second insulating layer 123. Consequently, the wiring pattern layer 140 is left on the second insulating layer 123. In and after FIG. 3P, the seed layer 282 is not shown.

In FIG. 3Q, a roughening treatment (a half etching treatment) is carried out over the surfaces of the second insulating layer 123 and the wiring pattern layer 140 and a so-called built-up resin 284 taking a shape of a film and containing an epoxy resin as a principal component (a content of a filler may be properly varied depending on a hardness or a flexibility which is required) is laminated to form an insulating layer (a third insulating layer) to be the second layer 124. For example, a laser beam is irradiated to form a via hole 290 in such a manner that the surface of the wiring pattern layer 140 is exposed.

By repeating the steps in FIGS. 3M to 3Q, subsequently, the via 142 of the second layer 124 and the wiring pattern layer 150 of the third layer 126 are formed. In the case in which the wiring board 120 has a lamination of four layers or more, furthermore, it is preferable to correspondingly repeat the steps of FIGS. 3M to 3Q.

In FIG. 3R, a seed layer 314 is formed on a surface (an upper surface) of an insulating layer to be the third layer 126 through electroless plating of Cu, and subsequently, a dry film resist 300 is laminated as a plating resist. For a method of forming the seed layer 314, it is also possible to use a thin film forming method other than the electroless Cu plating or the seed layer 314 may be formed by a conductive metal other than Cu.

Then, patterning (exposure and development) is carried out over the dry film resist 300 to form an electrode forming opening 310 for exposing a part of the seed layer 314. Next, the electrolytic Cu plating is carried out by feeding to the seed layer 314 to deposit Cu in a via hole 312 and the electrode forming opening 310 so that the via 152 and the third electrode pad 160 are formed. Thereafter, the dry film resist 300 is removed from the seed layer 314, and furthermore, the seed layer 314 in portions other than the third electrode pad 160 is removed. At steps in and after FIG. 3S, Cu is integrated in the seed layer 314 provided under the third electrode pad 160 and the seed layer 314 is therefore omitted.

In FIG. 3S, a solder resist 320 is laminated on a surface (an upper surface) of the insulating layer to be the third layer 126, thereby forming the insulating layer to be the fourth layer 128, and an opening 330 is then formed in such a manner that a central part of the third electrode pad 160 is exposed.

In FIG. 3T, the support substrate 200 is removed by wet etching to obtain the wiring board 120. It is also possible to use two support substrates 200 stuck to each other in a vertical direction as the support substrate 200 and to laminate the wiring board 120 on both upper and lower surface sides thereof. In that case, the two support substrates 200 are divided into two parts and are then removed by the wet etching.

As shown in FIG. 2, thereafter, the solder ball is loaded onto the first electrode pad 130 of the wiring board 120 and a reflow is carried out so that each terminal of the semiconductor chip 110 is connected to the electrode pad 130 through the solder bump 180 and the semiconductor chip 110 is thus mounted on the wiring board 120. The step of mounting the semiconductor chip 110 on the wiring board 120 is properly selected, and the semiconductor chip 110 is mounted on the wiring board 120 to meet the demand of a client in some cases and the semiconductor chip 110 is mounted on the wiring board 120 in a customer to which the wiring board 120 is delivered in the other cases, for example.

In the case in which a thermal stress is generated in the reflow because of the formation of the solder bump 180, moreover, a direction of advance of the thermal stress is blocked by the second electrode pad 132 and is absorbed in a direction along the boundary surface between the first insulating layer 121 and the second insulating layer 123 because the second electrode pad 132 is formed to be protruded in the radial direction (the planar direction) from the outside diameter of the first electrode pad 130. In the wiring board 120 according to the first embodiment, therefore, it is possible to prevent a crack from being generated in the second insulating layer 123 covering the outer periphery of the second electrode pad 132.

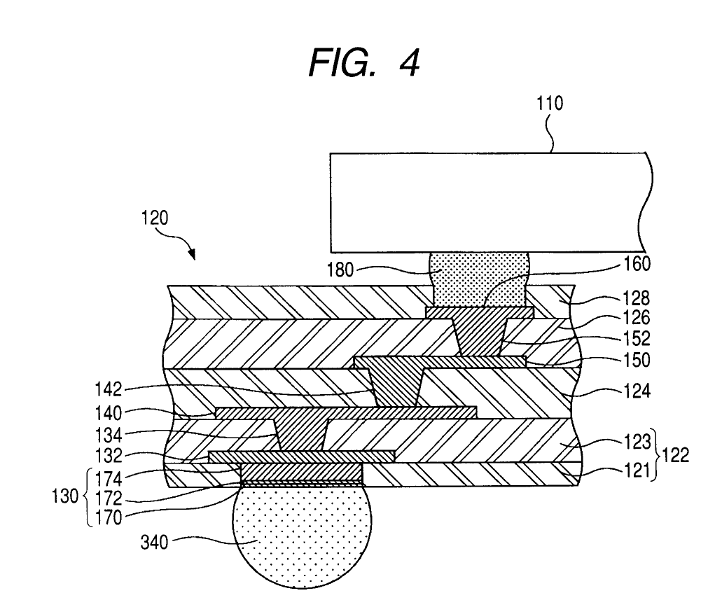

FIG. 4 is a view showing a variant of the first embodiment. In the variant, as shown in FIG. 4, a wiring board 120 is used with a vertical direction reversed to that in the first embodiment. More specifically, a semiconductor chip 110 is mounted on a third electrode pad 160 through a solder bump 180, and a solder ball is subjected to a reflow to form a solder bump 340 on a first electrode pad 130.

As shown in FIGS. 2 and 4, the semiconductor chip 110 may be mounted on the first electrode pad 130 or the third electrode pad 160 in the wiring board 120.

In the variant, the third electrode pad 160 maybe provided with a plated layer having an Au layer and an Ni layer laminated (the Au layer is laminated to be exposed to a surface).

In the variant, at the step shown in FIG. 3S, the semiconductor chip 110 may be loaded onto the wiring board 120 and a support substrate 200 may be then removed to complete a semiconductor device.

Also in the variant, moreover, an underfill resin having an insulating property may be filled between the semiconductor chip 110 and the wiring board 120.

Furthermore, the semiconductor chip 110 to be loaded onto the wiring board 120 according to the variant may be mounted through wire bonding.

### Second Embodiment

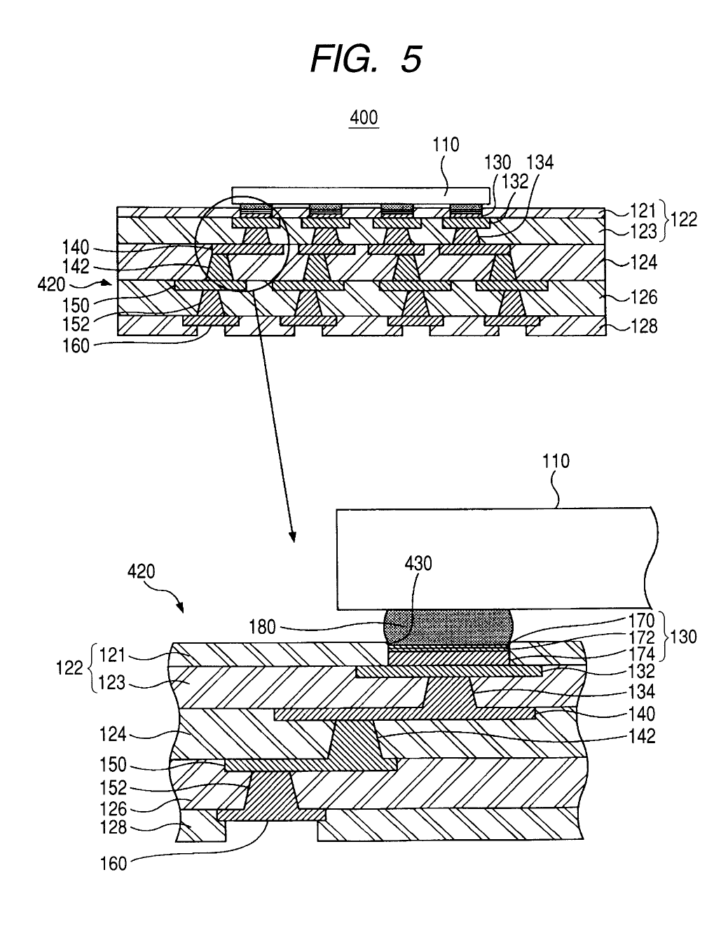

FIG. 5 is a longitudinal sectional view showing a semiconductor device to which a second embodiment of the wiring board is applied. In FIG. 5, the same portions as those in the first embodiment have the same reference numerals and description thereof will be omitted.

As shown in FIG. 5, in a wiring board 420 to be used in a semiconductor device 400 according to the second embodiment, a surface of a first electrode pad 130 (an end face on an Au layer 170 side) is formed on an electrode opening 430 which is concaved from a surface of a first insulating layer 121. Therefore, a reflow (a heat treatment) is carried out in a state in which a solder ball is inserted in the electrode opening 430, and a solder bump 180 is thus formed on the Au layer 170 side. In the semiconductor device 400 according to the second embodiment, an underfill resin having an insulating property may be filled between a semiconductor chip 110 and a wiring board 120.

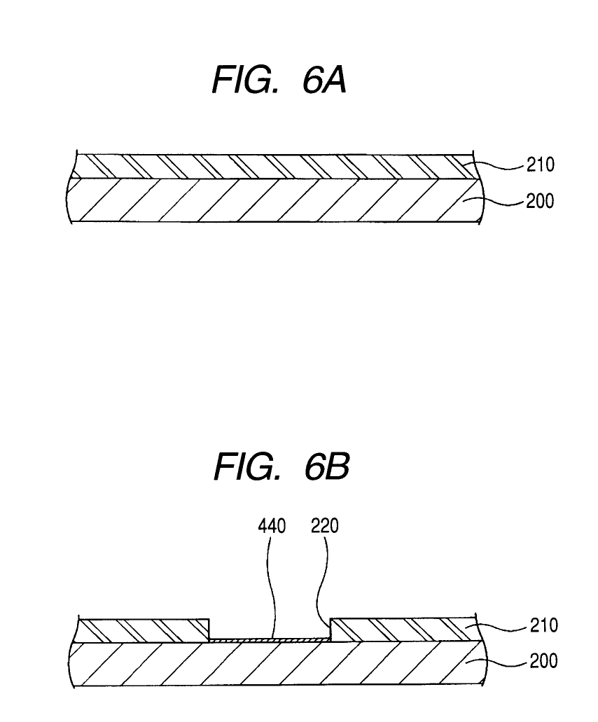

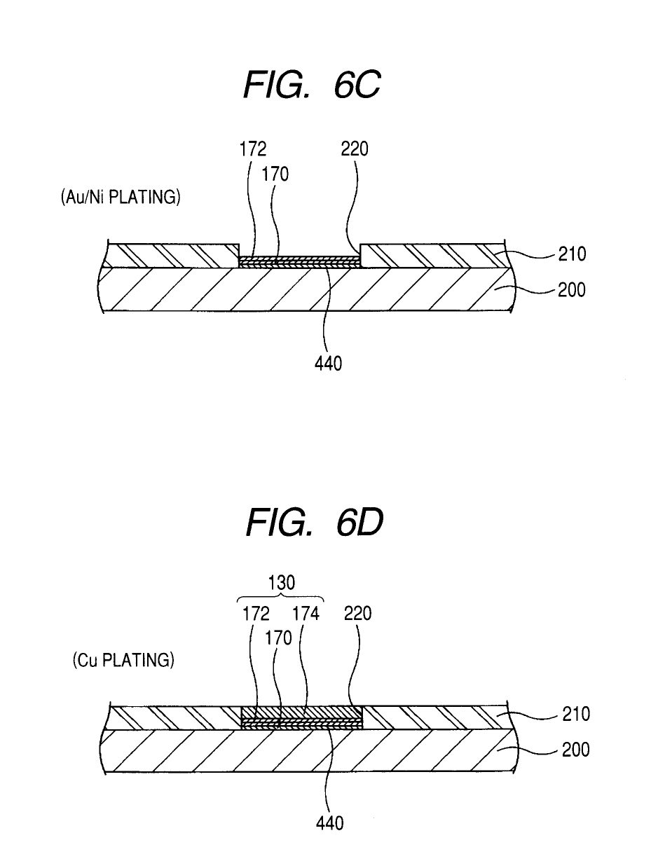

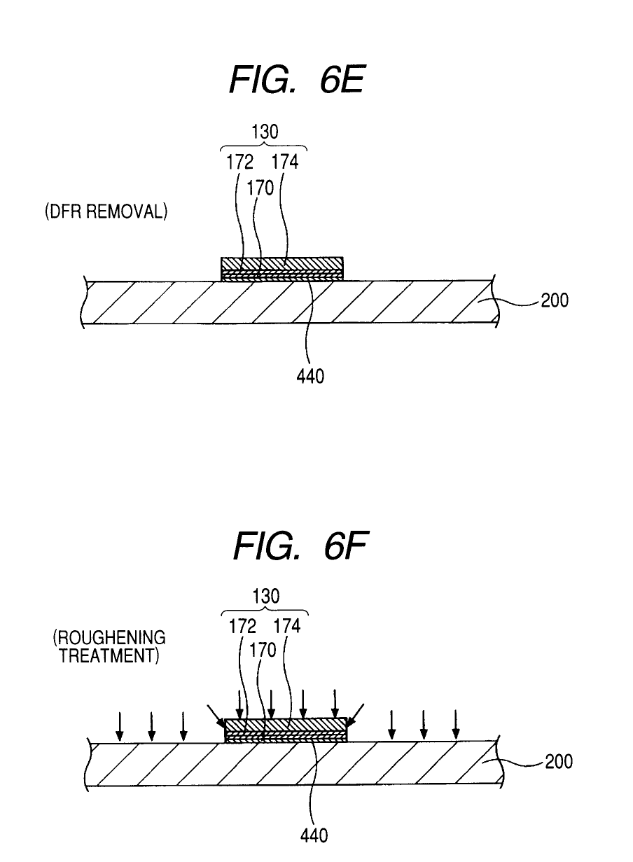

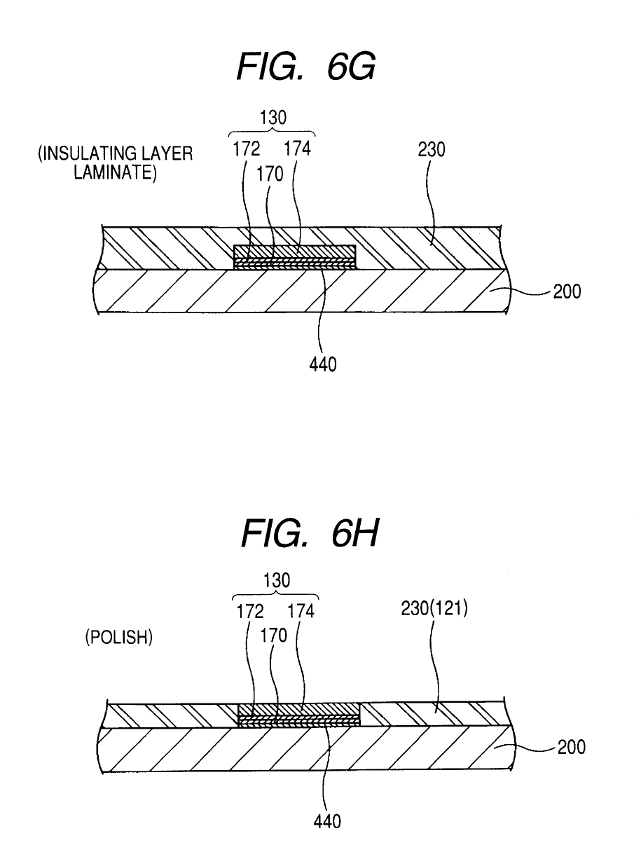

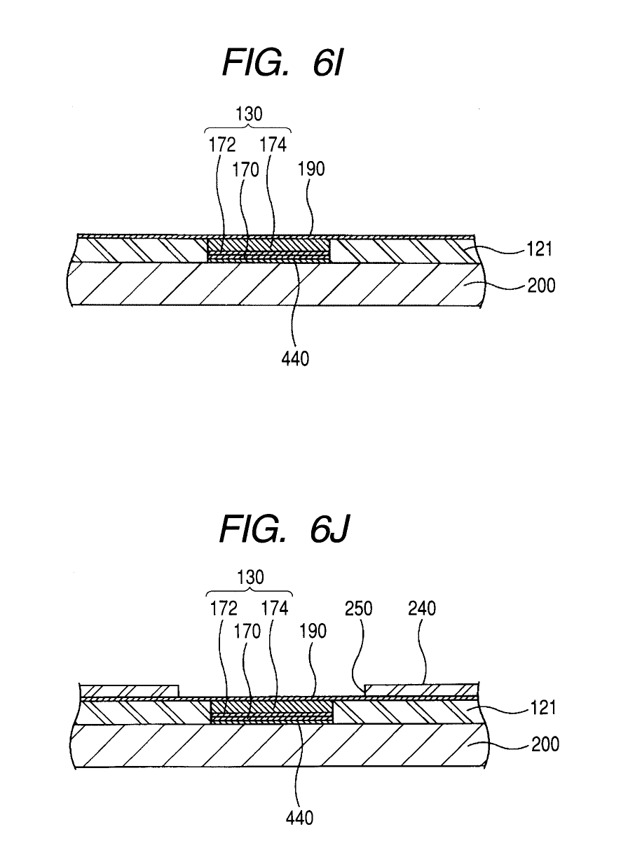

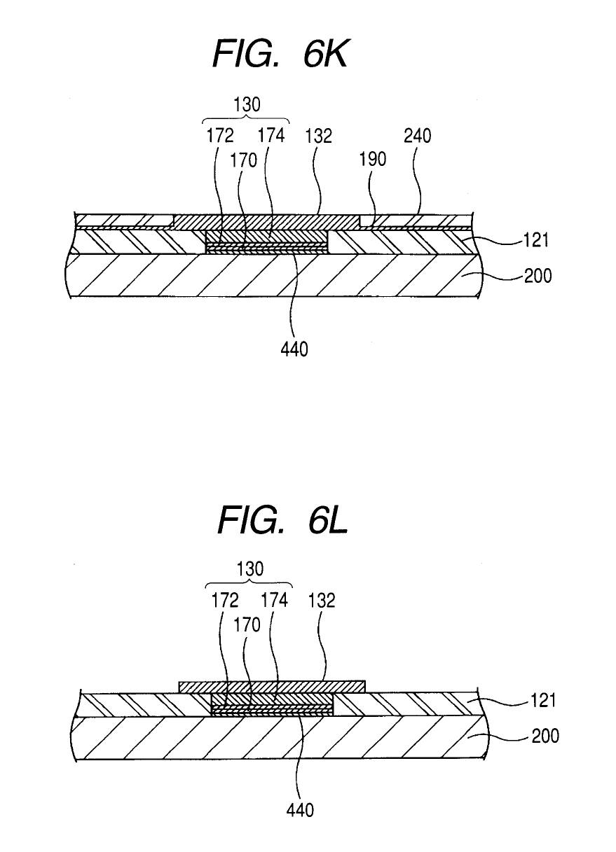

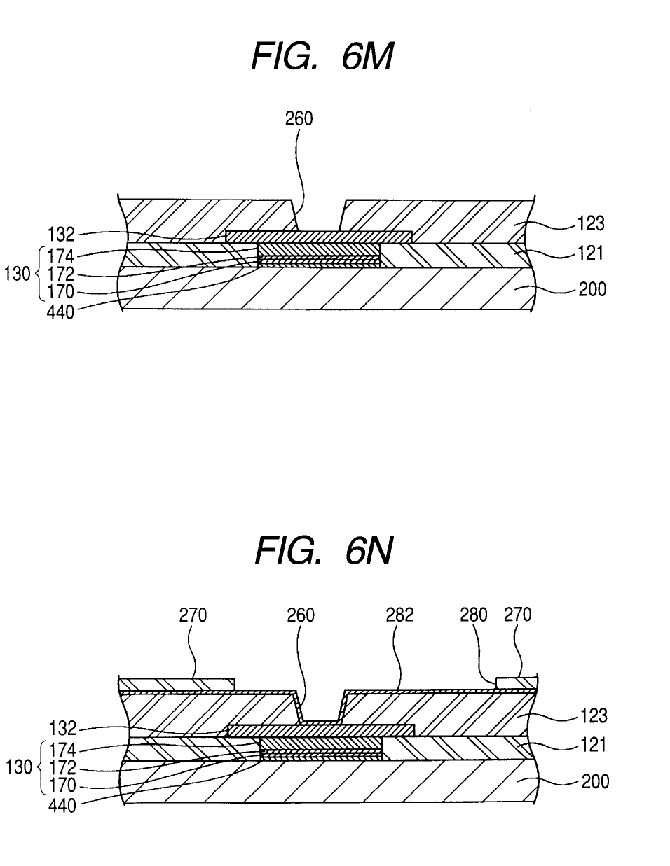

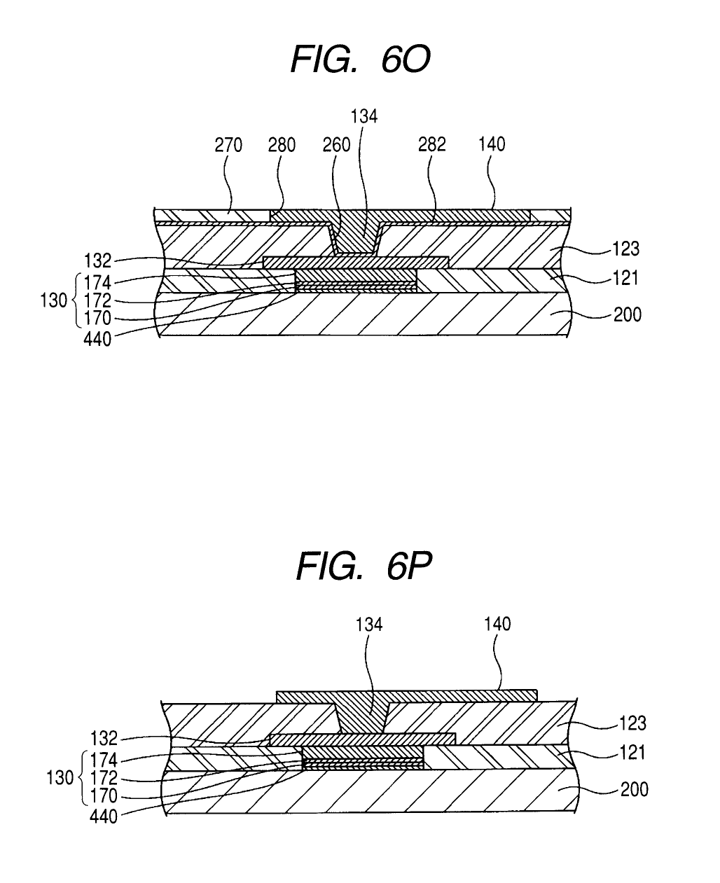

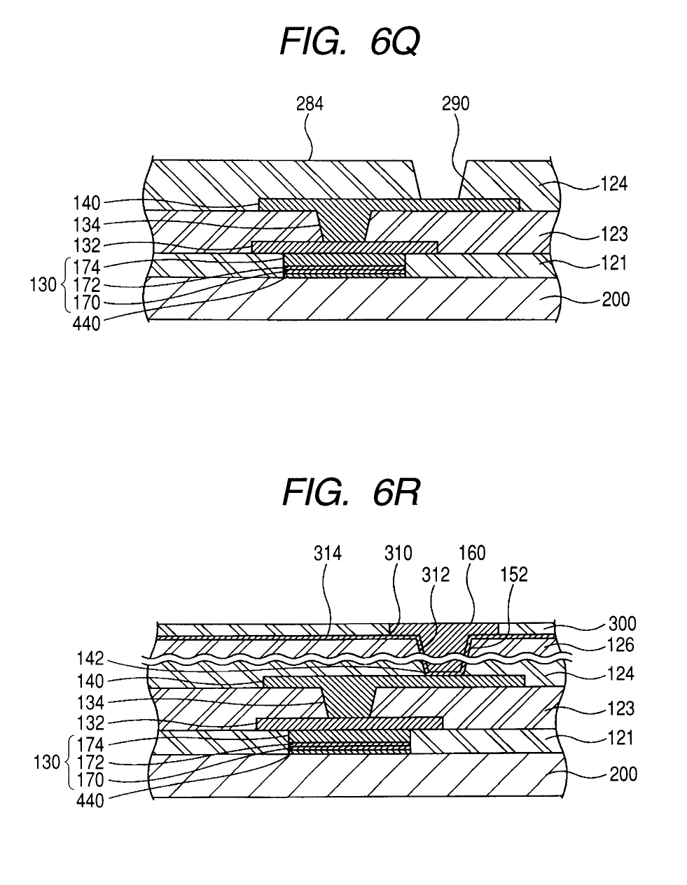

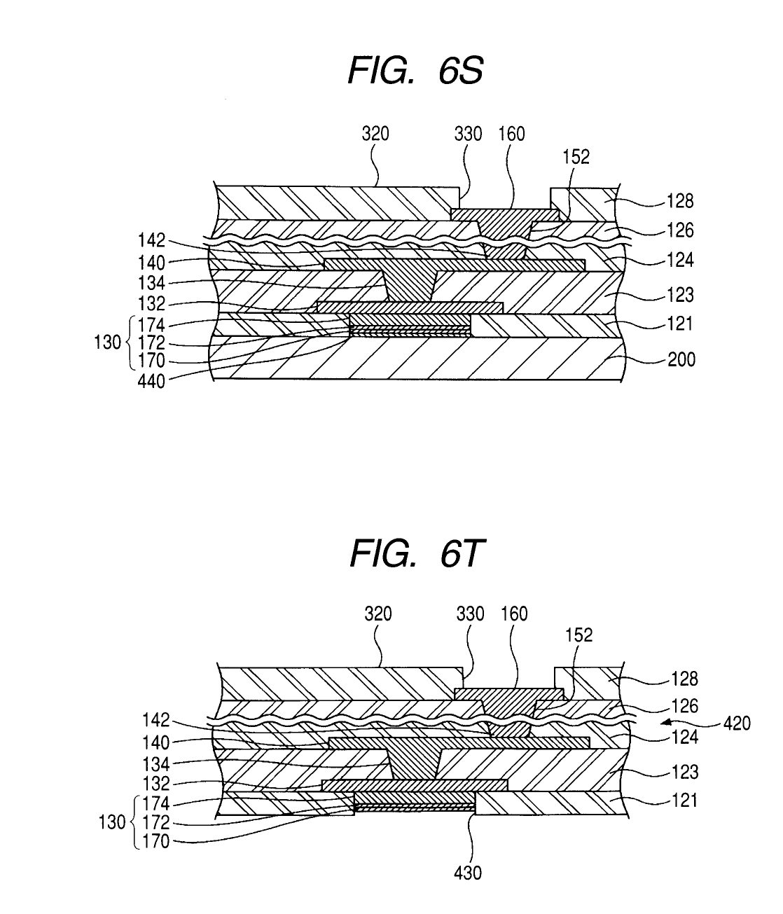

A method of manufacturing the wiring board 420 to be used in the semiconductor device 400 will be described with reference to FIGS. 6A to 6T. FIGS. 6A to 6T are views for explaining the methods (No. 1 to No. 20) of manufacturing the wiring board 420 according to the second embodiment. In FIGS. 6A to 6T, the respective layers are provided facedown (a vertically reverse direction to the lamination structure shown in FIG. 5) with the electrode pad 130 provided on a lower surface side of the wiring board 120.

In FIG. 6A, first of all, a support substrate 200 formed by a flat Cu plate or a Cu foil having a predetermined thickness is prepared. Then, a dry film resist 210 is laminated as a plating resist on an upper surface of the support substrate 200.

In FIG. 6B, a first electrode pad forming opening 220 for exposing a part of the support substrate 200 is formed on the dry film resist 210 through an exposure. An inside diameter of the first electrode pad forming opening 220 is equivalent to an outside diameter of the first electrode pad 130.

Subsequently, electrolytic Cu plating is carried out for an inner part of the first electrode pad forming opening 220 by setting the support substrate 200 as a feeding layer to deposit Cu on the support substrate 200 in the first electrode pad forming opening 220 so that a Cu layer 440 is formed.

In FIG. 6C, electrolytic plating is carried out by setting the support substrate 200 as a feeding layer to deposit Au on the Cu layer 440 in the first electrode pad forming opening 220, thereby forming the Au layer 170, and furthermore, to deposit Ni on the surface of the Au layer 170, thereby laminating an Ni layer 172.

In FIG. 6D, moreover, the electrolytic plating is carried out by setting the support substrate 200 as a feeding layer to deposit Cu on the Ni layer 172 in the first electrode pad forming opening 220, thereby laminating a Cu layer 174. Consequently, the Cu layer 440 and the first electrode pad 130 formed by the Au layer 170, the Ni layer 172 and the Cu layer 174 are provided in the first electrode pad forming opening 220.

In FIG. 6E, the dry film resist 210 is peeled from the support substrate 200 so that the Cu layer 440 and the first electrode pad 130 are left on the support substrate 200 in a laminating state.

Since the same processings as those in the steps shown in FIGS. 3F to 3S according to the first embodiment are carried out at steps shown in FIGS. 6F to 6S, description thereof will be omitted.

In FIG. 6T, the support substrate 200 is removed by wet etching, and furthermore, the Cu layer 440 is also removed to obtain the wiring board 420. In the wiring board 420 according to the second embodiment, the Cu layer 440 is removed so that the electrode opening 430 is formed on a lower surface side (a chip mounting side).

It is also possible to use two support substrates 200 stuck to each other in a vertical direction as the support substrate 200 and to laminate the wiring board 420 on both upper and lower surface sides thereof. In that case, the two support substrates 200 are divided into two parts and are then removed by the wet etching.

As shown in FIG. 5, thereafter, the solder ball is loaded onto the Au layer 170 of the electrode opening 430 and a reflow is thereafter carried out so that each terminal of the semiconductor chip 110 is connected to the first electrode pad 130 through the solder bump 180 and the semiconductor chip 110 is thus mounted on the wiring board 420. The step of mounting the semiconductor chip 110 on the wiring board 420 is properly selected, and the semiconductor chip 110 is mounted on the wiring board 420 to meet the demand of a client in some cases and the semiconductor chip 110 is mounted on the wiring board 420 in a customer to which the wiring board 120 is delivered in the other cases, for example.

In the wiring board 420 according to the second embodiment, thus, the electrode opening 430 is formed on the lower surface side (the chip mounting side). When the semiconductor chip 110 is to be mounted, therefore, the electrode opening 430 is subjected to the reflow (the heat treatment) so that the solder bump 180 is bonded to the Au layer 170 side of the first electrode pad 130. Consequently, the solder bump 180 is reliably bonded to the first electrode pad 130 and a bonding strength in a radial direction is also increased by a peripheral edge portion of the electrode opening 430.

In the case in which a thermal stress is generated in the reflow because of the formation of the solder bump 180, moreover, a direction of advance of the thermal stress is blocked by a second electrode pad 132 and is absorbed in a direction along the boundary surface between the first insulating layer 121 and a second insulating layer 123 because the second electrode pad 132 is widely formed to be protruded in the radial direction (the planar direction) from the outside diameter of the first electrode pad 130. In the wiring board 420 according to the second embodiment, therefore, it is possible to prevent a crack from being generated in the second insulating layer 123 covering the outer periphery of the second electrode pad 132 in the same manner as in the first embodiment.

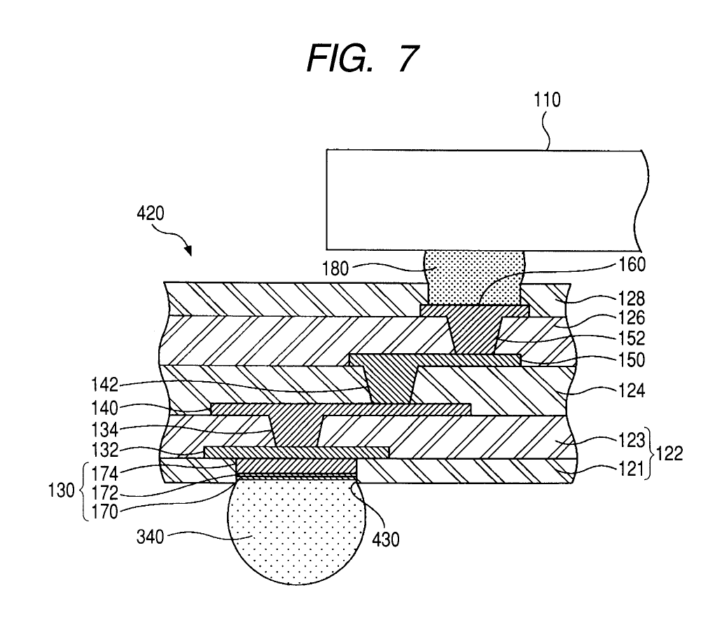

FIG. 7 is a view showing a variant of the second embodiment. In the variant, as shown in FIG. 7, the wiring board 420 is used with a vertical direction reversed to that in the second embodiment. More specifically, the semiconductor chip 110 is mounted on a third electrode pad 160 through the solder bump 180, and a solder ball is subjected to a reflow to form a solder bump 340 on the first electrode pad 130. In this case, the solder bump 340 has a bonding strength in a radial direction increased by the peripheral edge portion of the electrode opening 430.

As shown in FIGS. 5 and 7, the semiconductor chip 110 may be mounted on the first electrode pad 130 or the third electrode pad 160 in the wiring board 420.

In the variant, the third electrode pad 160 maybe provided with a plated layer having an Au layer and an Ni layer laminated (the Au layer is laminated to be exposed to a surface).

In the variant, at the step shown in FIG. 6S, the semiconductor chip 110 may be loaded onto the wiring board 420 and the support substrate 200 may be then removed to complete a semiconductor device.

Also in the variant, moreover, an underfill resin having an insulating property may be filled between the semiconductor chip 110 and the wiring board 120.

Furthermore, the semiconductor chip 110 to be loaded onto the wiring board 420 according to the variant may be mounted through wire bonding.

### INDUSTRIAL APPLICABILITY

It is a matter of course that the electrode pad according to the invention can be applied to an electrode pad for external connection such as a BGA (Ball Grid Array), a PGA (Pin Grid Array) and an LGA (Land Grid Array) in addition to an electrode pad for semiconductor chip mounting.

The invention is not restricted to a semiconductor device having a structure in which the solder bump 180 is formed but it is also possible to employ a structure in which an electronic component is loaded onto a substrate or a structure in which a wiring pattern is formed on a substrate. Therefore, it is a matter of course that the invention can also be applied to a flip chip bonded onto a substrate through a solder bump or a multilayer substrate or an interposer to which a circuit board is bonded through a solder bump, for example.

1. A method of manufacturing a wiring board, comprising:
a first step of forming a first electrode pad on a support substrate;
a second step of laminating, on a surface of the support substrate, a first insulating layer surrounding an outer periphery of the first electrode pad;
a third step of forming a second electrode pad which is wider in a planar direction than the outer periphery of the first electrode pad from a surface of the first electrode pad to that of the first insulating layer;
a fourth step of laminating a second insulating layer on surfaces of the second electrode pad and the first insulating layer;
a fifth step of forming, on a surface of the second insulating layer, a wiring layer to be electrically connected to the second electrode pad; and
a sixth step of removing the support substrate to expose the first electrode pad.

2. The method of manufacturing a wiring board according to claim 1, wherein
the second step includes a step of roughening the surface of the first electrode pad before laminating the first insulating layer.

3. The method of manufacturing a wiring board according to claim 1, wherein
the support substrate is formed of a metal,
the first step includes a step of forming a metal layer of the same type as the support substrate between the support substrate and the first electrode pad, and
the sixth step includes a step of removing the support substrate, removing the metal layer and forming a concave portion by an end face of the first electrode pad.

4. A method of manufacturing a semiconductor device using the method of manufacturing a wiring board according to claim 1, comprising the step of:
mounting a semiconductor chip on the first electrode pad through a solder bump.

5. A wiring board comprising:
a first electrode pad;
a first insulating layer surrounding an outer periphery of the first electrode pad; and
a second insulating layer laminated on a surface of the first electrode pad and that of the first insulating layer, wherein
a second electrode pad which is wider in a planar direction than an outer periphery of the first electrode pad is provided between the first electrode pad and the second insulating layer.

6. The method of manufacturing a wiring board according to claim 1, wherein
the first electrode pad has a diameter of approximately 70 to 100 μm and a thickness of approximately 5 to 25 μm,
the second electrode pad has a diameter which is greater than that of the first electrode pad by approximately 20 to 90% and has a thickness of approximately 2 to 15 μm.

7. The wiring board according to claim 5, wherein
the first electrode pad has a diameter of approximately 70 to 100 μm and a thickness of approximately 5 to 25 μm,
the second electrode pad has a diameter which is greater than that of the first electrode pad by approximately 20 to 90% and has a thickness of approximately 2 to 15 μm.

8. The method of manufacturing a wiring board according to claim 1, wherein
the first electrode pad has a structure in which only the Au layer and the Ni layer are laminated in such a manner that the Au layer is exposed to a surface of the wiring board.

9. The method of manufacturing a wiring board according to claim 1, wherein
the first electrode pad has a structure in which a lamination is carried out in order of the Au layer, the Pd layer, the Ni layer and the Cu layer or order of the Au layer, the Pd layer and the Ni layer in such a manner that the Au layer is exposed to the surface of the wiring board.

10. The wiring board according to claim 5, wherein
the first electrode pad has a structure in which only the Au layer and the Ni layer are laminated in such a manner that the Au layer is exposed to a surface of the wiring board.

11. The wiring board according to claim 5, wherein
the first electrode pad has a structure in which a lamination is carried out in order of the Au layer, the Pd layer, the Ni layer and the Cu layer or order of the Au layer, the Pd layer and the Ni layer in such a manner that the Au layer is exposed to the surface of the wiring board.

12. The method of manufacturing a wiring board according to claim 2, wherein
a surface roughness obtained by the roughening treatment has Ra=approximately 0.25 to 0.75 μm.
